(19) United States
(12) Patent Application Publication
(10) Pub. No.: US 2018/0249578 A1
(43) Pub. Date: Aug. 30, 2018

(54) SEMICONDUCTOR COMPONENT AND METHOD OF PRODUCING A SEMICONDUCTOR COMPONENT

(71) Applicant: OSRAM Opto Semiconductors GmbH, Regensburg (DE)

(72) Inventors: Frank Singer, Regenstauf (DE); Siegfried Herrmann, Neukirchen (DE)

(21) Appl. No.: 15/902,282

(22) Filed: Feb. 22, 2018

(30) Foreign Application Priority Data
Feb. 24, 2017 (DE) 10 2017 103 828.0

(51) Int. Cl. H05K 1/18; H01L 33/50; H01L 33/48; H01L 33/64

(52) U.S. Cl. CPC H05K 1/181; H01L 33/50; H05K 2201/10454; H01L 33/64; H01L 33/486

(57) ABSTRACT

A semiconductor component includes first and second connection contacts provided to electrically contact a semiconductor body, a carrier on which a semiconductor chip is arranged, the carrier including a base body including a chip mounting surface and a connection surface opposite the chip mounting surface and at least one side surface, that connects the chip mounting surface to the connection surface, a first electrically conductive contact layer electrically conductively connected to the first connection contact, and a second electrically conductive contact layer electrically conductively connected to the second connection contact, wherein the first and the second contact layer are applied to the base body and each include a first partial region arranged on the chip mounting surface, a second partial region arranged on a side surface and a third partial region arranged on the connection surface, and wherein the base body contains a radiation-transmissive base material.

### TECHNICAL FIELD

This disclosure relates to a semiconductor component, which is in particular an optoelectronic semiconductor component, which is suitable for surface mounting, and a method of producing a semiconductor component.

### BACKGROUND

There are known surface-mountable semiconductor components in which a semiconductor chip is arranged on a chip mounting surface of a carrier. In that case, connection contacts of the semiconductor chip can be electrically conductively connected to vias of the carrier, wherein the vias extend from the chip mounting surface through a carrier body of the carrier to a connection surface of the carrier opposite the chip mounting surface. The semiconductor chip can be electrically and mechanically connected to a connection carrier at the connection surface. Those designs are related to relatively high production costs since, for the production thereof, holes must first be introduced into the carrier body and filled with metal.

It could therefore be helpful to provide a more cost-efficient semiconductor component as well as a method producing such a semiconductor component.

### SUMMARY

We provide a semiconductor component including a semiconductor chip including a semiconductor body and a first and second connection contact, wherein the first and second connection contact are provided to electrically contact the semiconductor body, a carrier on which the semiconductor chip is arranged, the carrier including a base body including a chip mounting surface and a connection surface opposite the chip mounting surface and at least one side surface, that connects the chip mounting surface to the connection surface, a first electrically conductive contact layer electrically conductively connected to the first connection contact, and a second electrically conductive contact layer electrically conductively connected to the second connection contact, wherein the first and the second contact layer are applied to the base body and each include a first partial region arranged on the chip mounting surface, a second partial region arranged on a side surface and a third partial region arranged on the connection surface, and wherein the base body contains a radiation-transmissive base material.

We also provide a method of producing at least one semiconductor component including providing a base body unit including a first surface and a second surface opposite the first surface and at least one outer surface, which connects the first surface to the second surface, structuring of the base body unit in base body elements and recesses, wherein the recesses are laterally delimited by the base body elements, and the recesses extend from the first surface through the base body unit to the second surface or end in the base body unit such that a web is arranged in each case between a recess protruding from the first surface into the base body unit and a recess protruding from the second surface into the base body unit, forming a carrier unit by applying a contact coating to the first and second surface and to side surfaces of the base body elements, wherein the contact coating at the side surfaces includes in each case an interruption which extends in a lateral direction, singulating the carrier unit into a plurality of carrier elements, each including a base body element and a first and second contact region, wherein the first and second contact region are separated from one another by interruptions, forming a component assembly by applying semiconductor chips to a carrier element such that their first connection contacts electrically conductively connect to the first contact region and their second connection contacts electrically conductively connect to the second contact region, and singulating the component assembly into a plurality of semiconductor components.

### BRIEF DESCRIPTION OF THE DRAWINGS

FIGS. 1A and 1B show a schematic side view and a schematic perspective view of a semiconductor component according to a first example.

FIG. 2 shows a schematic perspective view of a semiconductor component according to a second example.

FIGS. 3A and 3C show schematic perspective views of a semiconductor component or a semiconductor body and FIG. 3B shows a schematic side view of a semiconductor component according to a third example.

FIGS. 4A and 4B show schematic side views of a semiconductor component according to a fourth and fifth example and FIG. 4C shows a schematic plan view of a carrier of the semiconductor components shown in FIGS. 4A and 4B.

FIG. 5 shows a schematic side view of a semiconductor component according to a sixth example.

FIGS. 6A and 6B show schematic side views of a semiconductor component according to seventh and eighth examples.

FIG. 7 shows a schematic perspective view of a semiconductor component according to a ninth example.

FIG. 8 shows a schematic side view of a semiconductor component according to a tenth example.

FIG. 9 shows a schematic perspective view of a semiconductor component according to an eleventh example.

FIGS. 10A to 10G show different steps of a method according to a first variant of producing at least one semiconductor component.

FIGS. 11A to 11C show different steps of a method according to a second variant of producing at least one semiconductor component.

FIG. 12 shows one step of a method according to a third variant of producing at least one semiconductor component.

FIG. 13 shows one step of a method according to a fourth variant of producing at least one semiconductor component.

### LIST OF REFERENCES

1 semiconductor component
2 semiconductor chip
3 semiconductor body
3A first main surface
3B second main surface
3C side surface
4 first semiconductor region
5 second semiconductor region
6 active zone
7 carrier substrate
8 first connection contact
9 second connection contact
10 carrier
11 base body
11A chip mounting surface
11B connection surface
11C side surface
11C partial surface
12 first contact layer
12A first partial region
12B second partial region
12C third partial region
13 second contact layer
13A first partial region
13B second partial region
13C third partial region
14 cover element
14A outer surface
14B recess
15 reflector element
16 base body unit
16A first surface
16B second surface
16C outer surface
17 base body element
17A side surface
18, 18A, 18B recess
19 mold
20 contact coating
20A first contact region
20B second contact region
21 interruption
22 carrier element
23 component assembly
24 web
25 insulation
26 enclosure
27 opening
A1, A2 lateral distance
L1, L2 lateral directions
T, T1, T2 separating line
V vertical direction

### DETAILED DESCRIPTION

Our semiconductor component comprises a semiconductor chip and a carrier, on which the semiconductor chip is arranged. In this case, the semiconductor chip can comprise a semiconductor body and a first and second connection contact for electrically contacting the semiconductor body. In particular, the semiconductor body has a first main surface and a second main surface opposite the first main surface and at least one side surface, which connects the first main surface to the second main surface. The number of side surfaces is determined by the geometry of the semiconductor body. The semiconductor body may have a prismatic shape. Here, in particular, the first and second main surface are designed to be polygonal, preferably at least quadrangular. For example, the semiconductor body can have a cuboid shape and accordingly four side surfaces. Furthermore, it is possible for the first and second main surface to be of hexagonal or octagonal design, and the semiconductor body to have correspondingly six or eight side surfaces. By the approximation to a cylindrical shape, as is the case, for example, with a hexagonal or octagonal configuration of the first and second main surface, the decoupling of radiation can be improved in a radiation-emitting semiconductor body.

The semiconductor component is preferably a radiation-emitting component, wherein the semiconductor body comprises an active zone provided to generate electromagnetic radiation. The term “electromagnetic radiation” in particular means an infrared, visible and/or ultra-violet electromagnetic radiation. During operation, a part of the generated radiation preferably passes through at least one of the main surfaces of the semiconductor body. Another part of the radiation can be decoupled through the at least one side surface of the semiconductor body.

The semiconductor body may comprise a carrier substrate and a first and second semiconductor region of different conductivity, the first and second semiconductor region being arranged on the carrier substrate, and an active zone arranged between the first and second semiconductor region. In particular, the carrier substrate is a growth substrate on which the first and second semiconductor region are epitaxially deposited. “Epitaxially deposited on the growth substrate” means that the growth substrate serves for the deposition and/or for the growth of the first and second semiconductor regions. For example, the first semiconductor region is in direct contact with the growth substrate. Preferably, the growth substrate is not detached after the growth of the first and second semiconductor regions, but remains in the semiconductor body. In particular, the first semiconductor region has an n-conductivity, while the second semiconductor region has a p-conductivity.

Materials based on nitride compound semiconductors are preferably qualified for the first and second semiconductor region of the semiconductor body. “Based on nitride compound semiconductors” means that at least one layer of the semiconductor regions comprises a nitride III/V compound semiconductor material, preferably AlₙGaₘIn₁₋ₙ₋ₘN, wherein 0≤n≤1, 0≤m≤1 and n+m≤1. In this case, the material need not necessarily have a mathematically exact composition according to the above formula. Rather, it can comprise one or more dopants and additional constituents which substantially do not change the characteristic physical properties of the AlₙGaₘIn₁₋ₙ₋ₘN material. For the sake of simplicity, however, the above formula includes only the essential constituents of the crystal lattice (Al, Ga, In, N), even if these can be replaced in part by small amounts of further substances.

The carrier or growth substrate preferably comprises or consists of sapphire, SiC and/or GaN. A sapphire substrate is transparent to short-wave visible radiation, in particular in the blue to green range.

In particular, the semiconductor chip is a volume emitter that emits the generated radiation substantially isotropically.

The first and second connection contact of the semiconductor chip are arranged on one of the surfaces of the semiconductor body, which include the first and second main surfaces and the at least one side surface. For example, the connection contacts can be arranged on the same surface. However, it is also possible for the two connection contacts to be formed on different surfaces, for example, on the first and second main surface. The first and second connection contacts are provided for electrically contacting the semiconductor body.

The carrier of the semiconductor component may comprise a base body and a first and second electrically conductive contact layer. Preferably, the first contact layer is electrically conductively connected to the first connection contact and the second contact layer is electrically conductively connected to the second connection contact.

The base body of the carrier can comprise a chip mounting surface and a connection surface opposite the chip mounting surface and at least one side surface, which connects the chip mounting surface to the connection surface. The number of side surfaces is determined by the geometry of the base body.

The base body may have a prismatic shape. In particular, in this case the chip mounting surface and the connection surface are designed to be polygonal, preferably at least quadrangular. For example, the base body can have a cuboid shape and accordingly four side surfaces. Furthermore, it is possible for the chip mounting surface and the connection surface to be of hexagonal or octagonal design, and the base body to have accordingly six or eight side surfaces.

Furthermore, the at least one side surface can be a surface composed of at least two partial surfaces. For example, the partial surfaces can be flat surfaces, the surface normals of which run transversely to one another, that is to say not in parallel to one another.

By the approximation to a cylindrical or spherical shape, as is the case, for example, by a hexagonal or octagonal configuration of the chip mounting surface and of the connection surface or by composing the side surfaces from a plurality of partial surfaces, the decoupling of radiation from the base body in a radiation-emitting semiconductor component can be improved.

In particular, the first and the second contact layer are applied to the base body and each comprise a first partial region arranged on the chip mounting surface, a second partial region arranged on a side surface and a third partial region arranged on the connection surface. In other words, the contact guiding in the carrier is not effected as before by holes in the carrier, but at flanks of the carrier. In particular, the base body is free of contact elements in its interior. The contact elements include, for example, vias or metal-filled holes. Furthermore, the base body can have side surfaces which are completely uncovered by the contact layers.

The first partial region of the first contact layer can have a lateral distance to the first partial region of the second contact layer. Furthermore, the third partial region of the first contact layer can have a lateral distance to the third partial region of the second contact layer. In addition, the second partial region of the first contact layer can have a lateral distance to the second partial region of the second contact layer, wherein the base body is arranged between the partial regions of the first and second contact layer. In this case, the lateral distance is preferably determined parallel to the chip mounting surface and/or connection surface.

Furthermore, the first partial region of the first contact layer can have a vertical distance to the third partial region of the first contact layer, wherein the base body is arranged between the first and third partial region of the first contact layer in the vertical direction. In this case, the vertical direction preferably runs transversely, in particular perpendicularly, to the chip mounting surface and/or connection surface. Furthermore, the first partial region of the second contact layer can have a vertical distance to the third partial region of the second contact layer, wherein the base body is arranged between the first and third partial region of the second contact layer in the vertical direction.

The base body advantageously contains a radiation-transmissive base material. “Radiation-transmissive” means in particular that at most 50%, preferably at most 10%, of the radiation emitted by the semiconductor body, which impinges on the base body, is absorbed by the base material. The base material can be transparent, that is to say allows for clear sight, or translucent, that is to say diffusely scattering. A comparatively high decoupling of radiation can be achieved by the radiation-transmissive base material.

Materials such as glass or plastic are particularly qualified as base material for the base body. Glass and thermosetting plastics are particularly well suited due to their temperature stability. A preferred glass material is, for example, borosilicate glass which has a higher coefficient of thermal expansion (CTE=3.3*10⁻⁶/K) than quartz glass (CTE=0.54*10⁻⁶/K) and thus differs less from the coefficient of thermal expansion of a material preferably used for the semiconductor body such as GaN (CTE=6.2*10⁻⁶/K) so that cracks that may occur due to thermal stresses occur more rarely. Further suitable plastics are thermoplastics, which, for example, due to easier deformability, allow more complex shapes than glass and furthermore have a lower density so that lighter components can be produced. Materials such as polycarbonate or polymethyl methacrylate, for example, are suitable for this purpose.

In a preferred configuration, the first and second contact layer are metallic layers. A “metallic layer” is a layer formed from a metal or a metal compound and characterized by at least one of the following properties: high electrical conductivity which decreases with increasing temperature; high thermal conductivity, ductility (deformability), metallic luster (mirror luster). Suitable materials for the metallic contact layers are, for example, Cu, Ni, Au, AuSn.

The second partial regions of the first and second contact layer may be arranged on different side surfaces and cover between 50% and 100% of the respective side surface. In a preferred configuration, the first partial regions of the first and second contact layer together cover at least 50% and less than 100% of the chip mounting surface. Furthermore, the third partial regions of the first and second contact layer together can cover at least 50% and less than 100% of the connection surface.

A large-area coverage of the surfaces of the base body by the contact layers, that is to say a degree of coverage of, in particular, at least 50%, advantageously leads to a higher reflectivity due to the reflecting properties of the contact layers. In addition, in large-area coverage, the heat produced during operation can be better dissipated from the semiconductor chip.

Alternatively, the second partial regions of the first and second contact layer are arranged on different side surfaces and cover more than 0% and less than 50% of the respective side surface. In a preferred configuration, the first partial regions of the first and second contact layer cover more than 0% and less than 50% of the chip mounting surface. Furthermore, the third partial regions of the first and second contact layer can cover more than 0% and less than 50% of the connection surface. For example, the contact layers can be embodied in strip-shaped fashion and extend from the chip mounting surface over the respective side surface to the connection surface.

A minimum coverage of the surfaces of the base body by the contact layers, that is to say a degree of coverage of in particular less than 50%, has the advantage in this case that the carrier has a higher radiation transmissibility which in turn leads to an improvement in the decoupling of radiation.

Preferably, the first, second and third partial region of the first contact layer have an identical lateral extent. Accordingly, the first, second and third partial region of the second contact layer can have an identical lateral extent. In addition, the first and second contact layer can have an identical lateral extent.

In a preferred configuration, the semiconductor chip projects beyond the carrier in at least one lateral direction. In other words, the semiconductor chip has a greater lateral extent than the carrier. As a result, the radiation can be emitted in the projecting region of the semiconductor chip on the side facing the carrier in a substantially unreduced way, that is to say without significant absorption losses at the carrier.

The semiconductor component may comprise a cover element which at least partially covers surfaces of the semiconductor chip and of the carrier. The semiconductor chip and the carrier can be arranged within the cover element. The cover element can be arranged downstream of the carrier and the semiconductor chip in lateral directions, that is to say, for example, in directions parallel to the chip mounting surface, and can protrude the semiconductor chip in the vertical direction, that is to say, for example, in a direction transverse, in particular perpendicular, to the chip mounting surface. The semiconductor chip can be hermetically encapsulated by the cover element so that the semiconductor chip is in particular temperature-resistant and resistant to aging. The cover element can have an outer surface, that is to say a surface which delimits the semiconductor component towards the outside, corresponding to the surface of a geometric body, for example, of a sphere or a cuboid. However, it is also possible for the outer surface to be a free-form surface. This means that the outer surface comprises regions which can be approximated by the surfaces of different geometric bodies. Advantageously, the cover element may comprise at least one convexly shaped surface, whereby the cover element likewise has the effect of a lens.

Preferably, at its underside the carrier is uncovered by the cover element. In particular, the third partial regions of the first and second contact layer are uncovered by the cover element. As a result, it is possible for the semiconductor component to be electrically connected by the third partial regions of the first and second contact layer. Thus, the semiconductor component is suitable for surface mounting.

The cover element may contain glass or plastic or consist of one of these materials. Preferably, the cover element is formed from the same material as the base body of the carrier. This has the advantage that the two elements have the same coefficient of thermal expansion and that the risk of cracks due to different thermal expansion is reduced.

In addition, the cover element or the material from which the cover element is formed is advantageously radiation-transmissive. In this context, too, “radiation-transmissive” in particular means that at most 50%, preferably at most 10%, of the radiation emitted by the semiconductor body, which impinges on the cover element, is absorbed by the material used for the cover element. In this case, the material of the cover element can be transparent, that is to say allows for clear sight, or translucent, that is to say diffusely scattering. A comparatively high decoupling of radiation can be achieved by the radiation-transmissive material. The cover element, in which, in particular, the semiconductor chip is embedded, represents an enlarged emission body compared to the semiconductor chip.

The cover element may be a sealing, in which the unit comprising the semiconductor chip and the carrier is embedded. The sealing can be formed mainly from a radiation-transmissive material.

Alternatively, the cover element is a self-supporting three-dimensional element, which is designed, for example, in the shape of a cuboid, in particular in the shape of a cube. The cover element can comprise an opening into which the unit comprising the semiconductor chip and the carrier is inserted. In particular, the opening corresponds in shape and size to the unit comprising the semiconductor chip and the carrier. A mechanical connection between the cover element and the component unit can be achieved, for example, by the cover element being melted at its underside. After cooling, the cover element is then fixed to the carrier.

Furthermore, the cover element can contain at least one phosphor, which converts at least a part of the radiation emitted by the semiconductor body into radiation of a different wavelength.

Furthermore, the semiconductor component can comprise a conversion element which is arranged on the semiconductor chip. The conversion element can convert at least a part of the radiation emitted by the semiconductor body into radiation of a different wavelength.

Furthermore, the semiconductor component can comprise a reflector element, which encloses the carrier in lateral directions and does not protrude the chip mounting surface of the carrier in the vertical direction. In particular, the reflector element can be an integral part of the cover element. For this purpose, the sealing can contain, for example, reflecting particles such as particles made of TiO₂, for example. Furthermore, it is possible for the cover element to be provided with a reflective coating.

Hereinafter, a method is described which is suitable to produce a semiconductor component as described above. Features described in connection with the semiconductor component can therefore also be relied on for the method and vice versa.

The method of producing at least one semiconductor component may comprise the following steps:
providing a base body unit comprising a first surface and a second surface opposite the first surface and at least one outer surface, which connects the first surface to the second surface,
structuring of the base body unit in base body elements and recesses, wherein the recesses are laterally, that is to say in particular in directions parallel to the first and/or second surface, delimited by the base body elements, and wherein the recesses extend from the first surface through the base body unit to the second surface or end in the base body unit such a way that a web is arranged in each case between a recess protruding from the first surface into the base body unit and a recess protruding from the second surface into the base body unit,
forming a carrier unit by applying a contact coating to the first and second surface and to side surfaces of the base body elements, wherein the contact coating at the side surfaces comprises in each case an interruption which extends in a lateral direction,
singulating the carrier unit into a plurality of carrier elements, each comprising a base body element and a first and second contact region, wherein the first and second contact region are separated from one another by interruptions,
forming a component assembly by applying semiconductor chips to a carrier element such that their first connection contacts are electrically conductively connected to the first contact region and their second connection contacts are electrically conductively connected to the second contact region, singulating the component assembly into a plurality of semiconductor components.

During singulation, a plurality of carriers are preferably formed from one carrier element. Accordingly, a plurality of base bodies are formed from one base body element, and a plurality of first contact layers are formed from the first contact region and a plurality of second contact layers are formed from the second contact region.

Preferably, the first and second surface of the base body unit are completely covered by the contact coating. However, it is also possible for the first and second surface of the base body unit to be only partially covered by the contact coating. For example, the contact coating can be applied to the surfaces in parallel strips, which extend transversely, in particular perpendicularly, to main extension directions of the recesses.

In a preferred configuration, the base body unit is a cuboid unit, for example, a plate. In particular, the base body unit can be a glass or plastic plate. Base body units of this type can be produced cost-efficiently.

A base body unit formed from plastic can, for example, be produced by a molding method. A molding method means a method with which a molding compound or a base material is configured preferably under the influence of pressure in accordance with a predetermined shape and, if necessary, cured. In particular, “molding method” includes molding, film assisted molding, injection molding, transfer molding and compression molding. When producing the base body unit by a molding method, the base material, from which the base body unit is produced, can already be provided with a structuring by a suitable shape of a molding device used.

Alternatively, the structuring of the base body unit can be carried out subsequently. For example, the recesses in the base body unit can be produced by hot stamping. In this case, the base body unit is heated, and the recesses are produced in the base body unit by a stamping tool. Furthermore, the recesses can be produced by mechanical and/or chemical processing such as, for example, lasering, sawing, etching.

To produce the interruptions in the contact coating, the following steps may be carried out:
introducing the structured base body unit with its second surface into a mold, wherein the mold comprises elevations, which engage in the recesses of the base body unit and partially cover the side surfaces of the base body elements,
producing the contact coating on uncovered regions of the base body unit,
introducing the structured base body unit with its first surface into the mold, wherein the elevations engage in the recesses of the base body unit and partially cover the side surfaces of the base body elements, and
producing the contact coating on uncovered regions of the base body unit.

The degree of coverage of the side surfaces by the elevations of the mold in the vertical direction is preferably more than 50% and in the lateral direction, in particular, 100%.

Furthermore, in this example of a method, the recesses are formed in particular continuously, that is to say they extend from the first surface through the base body unit to the second surface.

If the recesses are not formed continuously so that in each case a web is arranged between a recess protruding from the first surface into the base body unit and a recess protruding from the second surface into the base body unit, this web can prevent in the production of the contact coating a deposition of the contact coating on the side surfaces of the adjacent base body elements. By removal of the webs, the contact coating then comprises interruptions on the side surfaces.

A further possibility for the production of the interruptions consists in using a shadow mask in the production of the contact coating, for example, a wire cover, the shadow mask covering during the coating process the positions at which deposition of the contact coating is to be prevented.

In a preferred configuration, the contact coating is a metallization. Suitable materials for the contact coating are, for example, Cu, Ni, Au, AuSn. For example, a basic layer of the contact coating can be sputtered on. This basic layer can be reinforced galvanically.

For example, the singulation of the carrier unit into a plurality of carrier elements, each of which comprise a base body element and a first and a second contact region, can be carried out by dividing by a water jet or sandjet if the base body unit is made of glass. Moreover, a singulation is possible by laser separation or sawing.

Furthermore, the singulation of the component assembly, which comprises a carrier element and a plurality of semiconductor chips arranged thereon, can be carried out by laser separation or sawing.

The component units, each of which may comprise a carrier and a semiconductor chip arranged thereon, can each be provided with a cover element. In particular, the cover element comprises an opening into which the unit can be inserted. Preferably, the cover element is melted at its underside, wherein the cover element is fixed to the carrier after cooling.

The method described in which the production of holes in the carrier and the filling thereof is omitted represents a cost-efficient method for the production of semiconductor components.

Further advantages and developments of the method and the semiconductor component will become apparent from the examples described below in association with the Drawings.

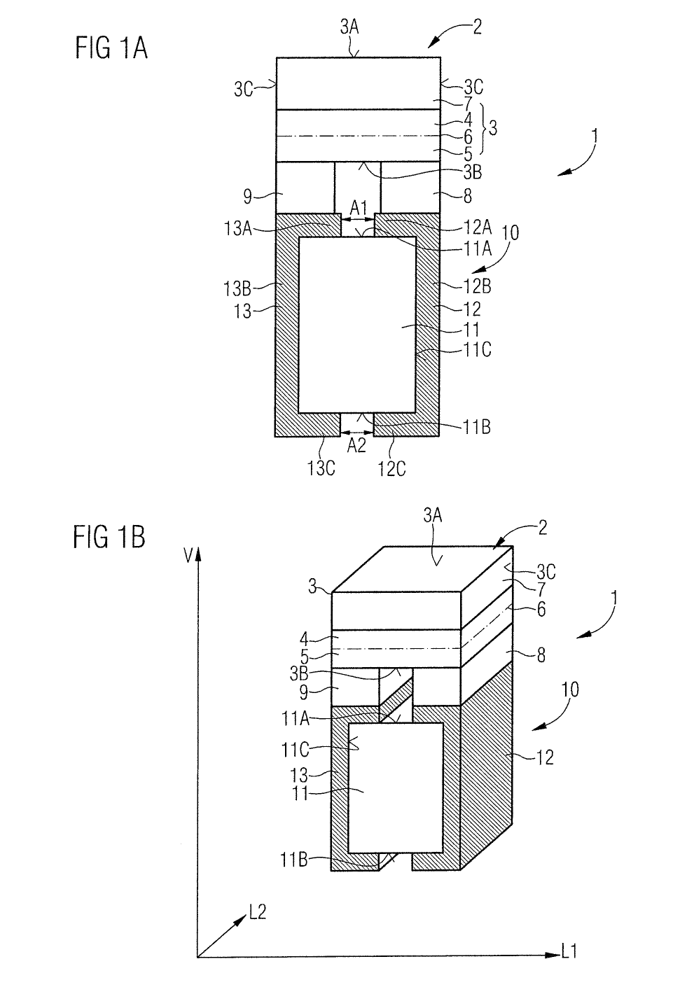

FIGS. 1A and 1B show a first example of a semiconductor component 1. The semiconductor component 1 comprises a semiconductor chip 2 and a carrier 10, on which the semiconductor chip 2 is arranged. The semiconductor chip 2 comprises a semiconductor body 3 and a first connection contact 8 and a second connection contact 9.

The semiconductor body 3 has a first main surface 3A and a second main surface 3B opposite the first main surface 3A, and a plurality of side surfaces 3C, which connect the first main surface 3A to the second main surface 3B. The semiconductor body 3 has a prismatic shape. The first and second main surface 3A, 3B are configured polygonally, preferably quadrangularly. In particular, the semiconductor body 3 has a cuboid shape and accordingly four side surfaces 3C.

Preferably, the semiconductor body 3 comprises a carrier substrate 7 and a first semiconductor region 4 and a second semiconductor region 5 of different conductivity, the first and second semiconductor region 4, 5 being grown on the carrier substrate 7, and comprises an active zone 6 arranged between the first and second semiconductor region 4, 5, the active zone 6 emitting radiation during operation. The carrier substrate 7 preferably consists of sapphire and is transmissible for the radiation emitted from the active zone 6. Materials preferably based on nitride compound semiconductors such as already mentioned above come into account for the first and second semiconductor region 4, 5 of the semiconductor body 3. Preferably, the semiconductor chip 2 is a flip-chip, wherein the carrier substrate 7 is arranged on a side of the semiconductor chip 2 facing away from the carrier 10. Both connection contacts 8, 9 are arranged on the side of the second main surface 3B, that is to say on a side of the semiconductor chip 2 facing the carrier 10. For example, the first connection contact 8 can be electrically conductively connected to the first semiconductor region 4. Further, the second connection contact 9 can be electrically conductively connected to the second semiconductor region 5. In particular, the second connection contact 9 is arranged in direct contact with the second semiconductor region 5. The first connection contact 8, however, can comprise at least one via, which extends from the second main surface 3B through the active zone 6 to the first semiconductor region 4 (not shown). Preferably, the first semiconductor region 4 is an n-doped region, and accordingly the first connection contact 8 is an n-contact. Furthermore, the second semiconductor region 5 can be a p-doped region and accordingly the second connection contact 9 can be a p-type contact.

In operation, radiation emerges in particular through all surfaces of the semiconductor body 3, that is to say through the first and second main surface 3A, 3B and through all four side surfaces 3C.

The carrier 10 of the semiconductor component 1 comprises a base body 11 and a first electrically conductive contact layer 12 and a second electrically conductive contact layer 13, which are applied to the base body 11. Preferably, the first contact layer 12 is electrically conductively connected to the first connection contact 8 and the second contact layer 13 is electrically conductively connected to the second connection contact 9. In a preferred configuration, the first and second contact layer 12, 13 are metallic layers. Suitable materials for the metallic contact layers 12, 13 are, for example, Cu, Ni, Au, AuSn.

The base body 11 of the carrier 10 has a chip mounting surface 11A and a connection surface 11B opposite the chip mounting surface 11A and at least one side surface 11C, which connects the chip mounting surface 11A to the connection surface 11B. The base body 11 has a prismatic shape, which is in particular cuboid so that the base body 11 has four side surfaces 11C.

In particular, the first and second contact layer 12, 13 each comprise a first partial region 12A, 13A arranged on the chip mounting surface 11A, a second partial region 12B, 13B arranged on a side surface 11C, and a third partial region 12C, 13C arranged on the connection surface 11B. In other words, the contact guiding in the carrier 10 is not effected as before by holes in the carrier, but at flanks of the carrier 10. In particular, the base body 11 is free of contact elements in its interior. The contact elements include, for example, vias or metal-filled holes.

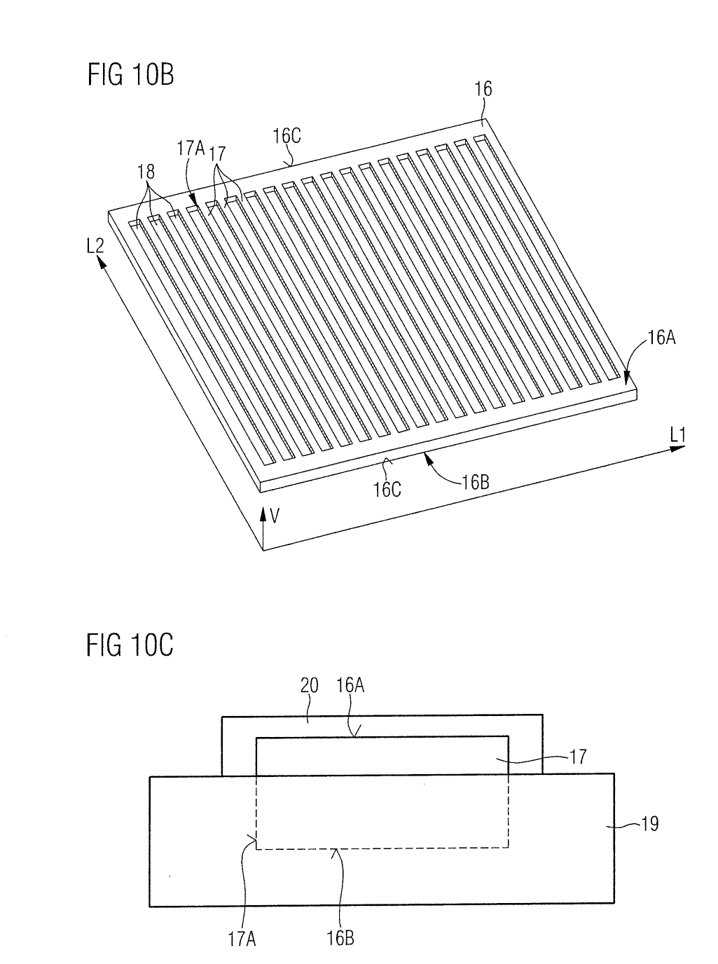

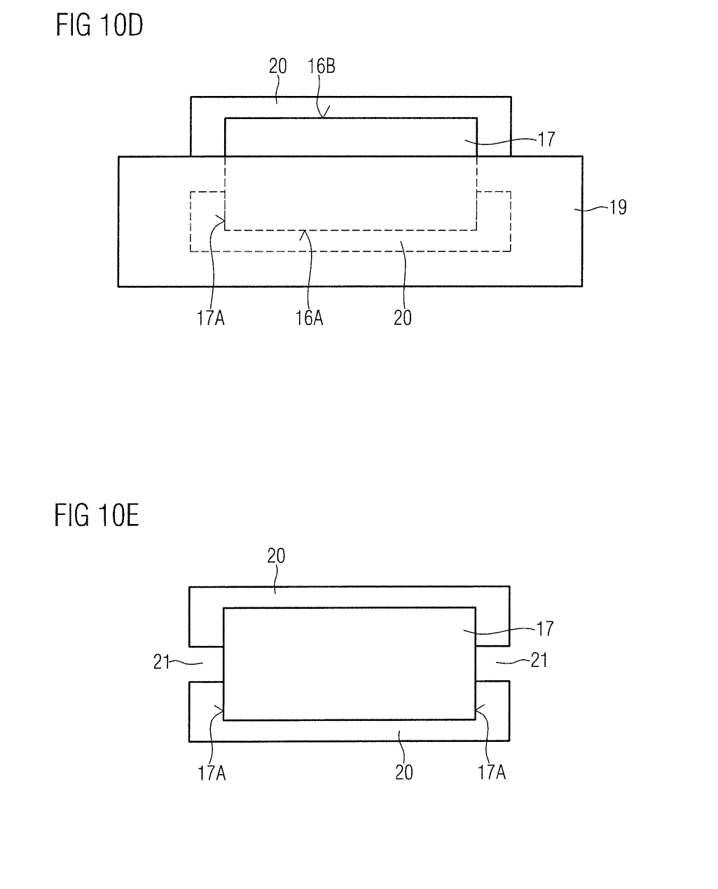

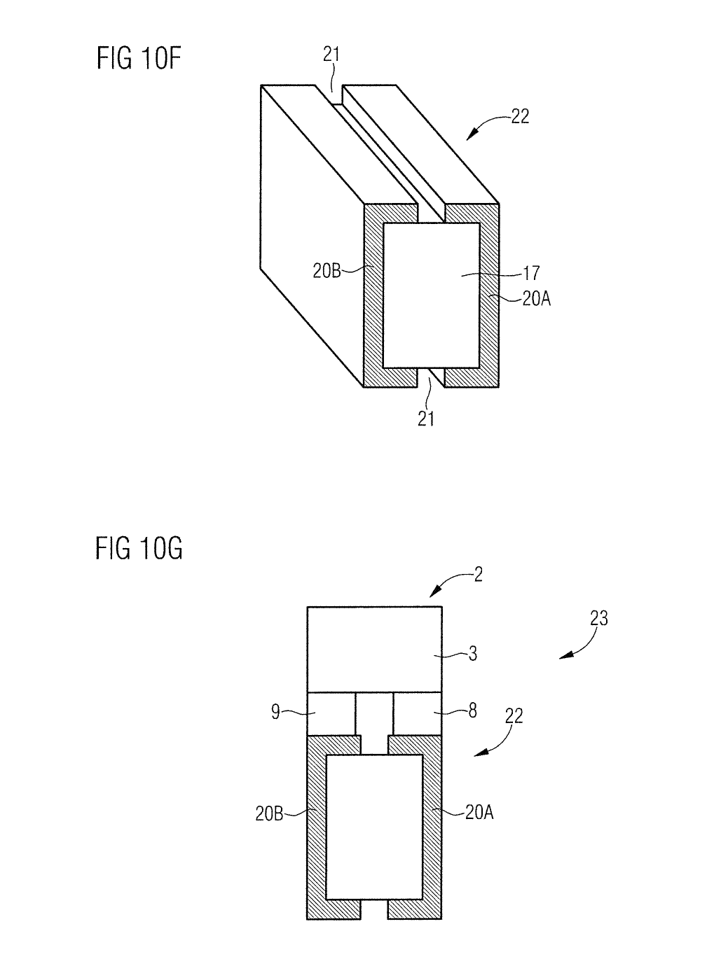

The first partial region 12A of the first contact layer 12 can have a lateral distance Al to the first partial region 13A of the second contact layer 13, wherein the lateral distance al is determined in a lateral direction L1 parallel to the chip mounting surface 11A. Furthermore, the third partial region 12C of the first contact layer 12 can have a lateral distance A2 to the third partial region 13C of the second contact layer 13, wherein the lateral distance A2 is determined parallel to the connection surface 11B. The contact layers 12, 13 are spaced apart from one another due to interruptions 21 in the contact coating 20 (see FIG. 10E).

Furthermore, the second partial region 12B of the first contact layer 12 can have a lateral distance to the second partial region 13B of the second contact layer 13, wherein the base body 11 is arranged between these partial regions 12B, 13B of the first and second contact layer 12, 13. Furthermore, the first partial region 12A of the first contact layer 12 can have a vertical distance to the third partial region 12C of the first contact layer 12, wherein the base body 11 is arranged in the vertical direction V between the first and third partial region 12A, 12C of the first contact layer 12. The vertical direction V preferably runs transversely, in particular perpendicularly to the chip mounting surface 11A and/or connection surface 11C. Furthermore, the first partial region 13A of the second contact layer 13 can have a vertical distance to the third partial region 13C of the second contact layer 13, wherein the base body 11 is arranged in the vertical direction V between the first and third partial region 13A, 13C of the second contact layer 13.

Advantageously, the first, second and third partial region 12A, 12B, 12C of the first contact layer 12 have an identical lateral extent which is determined in lateral direction L2. Accordingly, the first, second and third partial region 13A, 13B, 13C of the second contact layer 13 can have an identical lateral extent. In addition, the first and second contact layer 12, 13 can have an identical lateral extent.

In the example illustrated in FIGS. 1A and 1B, the semiconductor chip 2 does not project laterally beyond the carrier 10. The lateral extent of the semiconductor chip 2 is thus not greater than the lateral extent of the carrier 10.

The base body 11 advantageously contains a radiation-transmissive base material. In this context, “radiation-transmissive” means in particular that at most 50%, preferably at most 10%, of the radiation emitted by the semiconductor body 3, which impinges on the base body 11, is absorbed by the base material. The base material can be transparent, that is to say allows for clear sight, or translucent, that is to say diffusely scattering. A comparatively high decoupling of radiation can be achieved by the radiation-transmissive base material. Glass and plastic are suitable as base material for the base body 11.

In the first example illustrated in connection with FIGS. 1A and 1B, the base body 11 is covered by the contact layers 12, 13 for the most part, that is to say by more than 50%. The second partial regions 12B, 13B of the first and second contact layer 12, 13 cover in particular 100% of the respective side surface 11C. Furthermore, the first partial regions 12A, 13A of the first and second contact layer 12, 13 together cover at least 50% and less than 100% of the chip mounting surface 11A. Furthermore, the third partial regions 12C, 13C of the first and second contact layer 12, 13 together can cover at least 50% and less than 100% of the connection surface 11C. The other side surfaces 11C of the base body 11 are uncovered by the contact layers 12, 13.

A large-area coverage of the surfaces 11A, 11B, 11C of the base body 11, that is to say a degree of coverage of at least 50%, by the contact layers 12, 13 advantageously leads to a higher reflectivity due to the reflecting properties of the contact layers 12, 13. In addition, in the case of large-area coverage, the heat produced during operation can be better dissipated from the semiconductor chip 2.

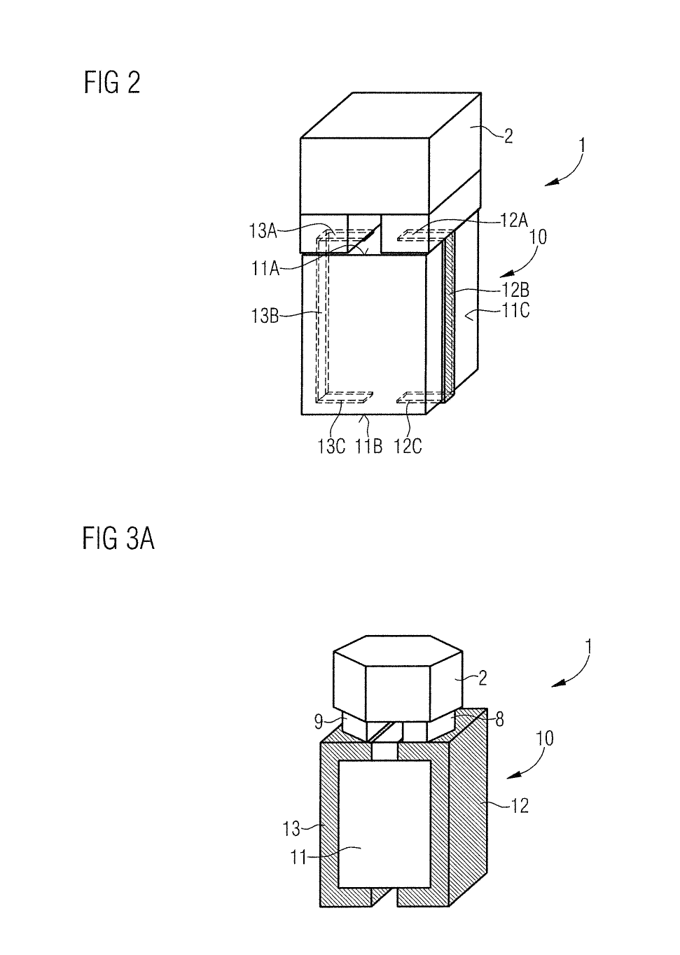

FIG. 2 shows a second example of a semiconductor component 1. With regard to the semiconductor chip 2, the semiconductor component 1 preferably does not differ from the first example. However, there are differences concerning the carrier 10. The second partial regions 12B, 13B of the first and second contact layer 12, 13 are arranged on different, opposite side surfaces 11C of the base body 11 and cover more than 0% and less than 50% of the respective side surface 11C. Furthermore, the first partial regions 12A, 13A of the first and second contact layer 12, 13 together cover more than 0% and less than 50% of the chip mounting surface 11A. Moreover, the third partial regions 12C, 13C of the first and second contact layer 12, 13 together can cover more than 0% and less than 50% of the connection area 11B. As illustrated, the contact layers 12, 13 can be embodied in strip-shaped fashion and extend starting from the chip mounting surface 11A over the respective side surface 11C to the connection surface 11B.

A minimum coverage of the surfaces 11A, 11B, 11C of the base body 11 as in the second example, that is to say a degree of coverage of less than 50% by the contact layers 12, 13, has the advantage that in this case the carrier 10 has a higher radiation transmissibility, which in turn leads to an improvement of the decoupling of radiation.

The first, second and third partial region 12A, 12B, 12C of the first contact layer 12 advantageously have an identical lateral extent. Accordingly, the first, second and third partial region 13A, 13B, 13C of the second contact layer 13 can have an identical lateral extent. In addition, the first and second contact layer 12, 13 can have an identical lateral extent.

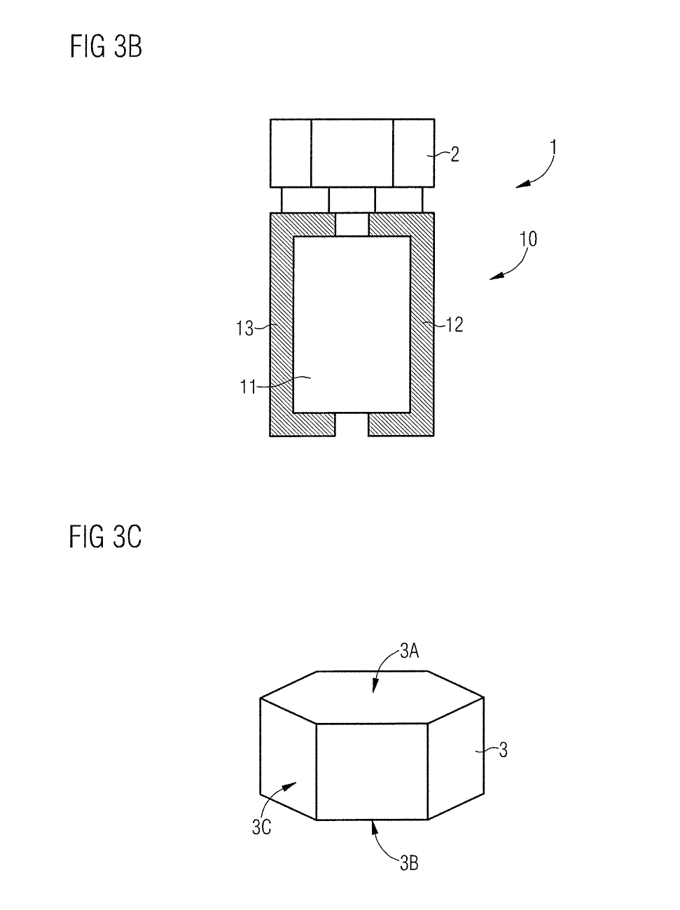

FIGS. 3A to 3C show a third example of a semiconductor component 1. With regard to the carrier 10, the semiconductor component 1 preferably does not differ from the first and second examples. The semiconductor body 3 also has a prismatic shape, but this is not cuboid. The first and second main surface 3A, 3B are embodied hexagonally. The semiconductor body 3 accordingly has six side surfaces 3C. By the approximation to a cylindrical shape, as is the case with a hexagonal configuration of the first and second main surface 3A, 3B, the decoupling of radiation from the semiconductor body 3 can be improved.

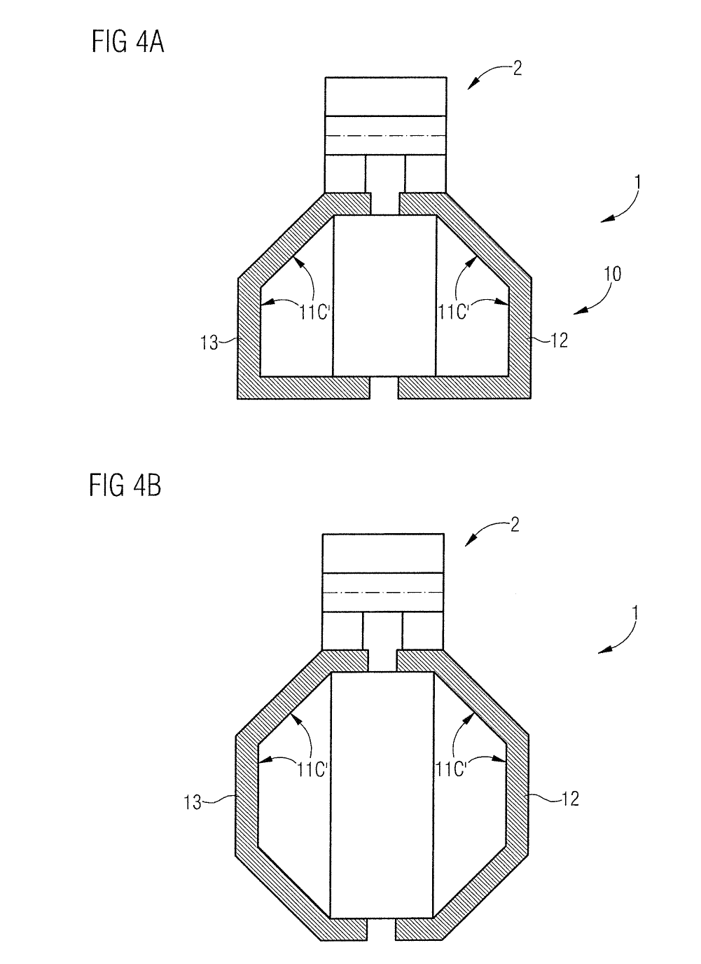

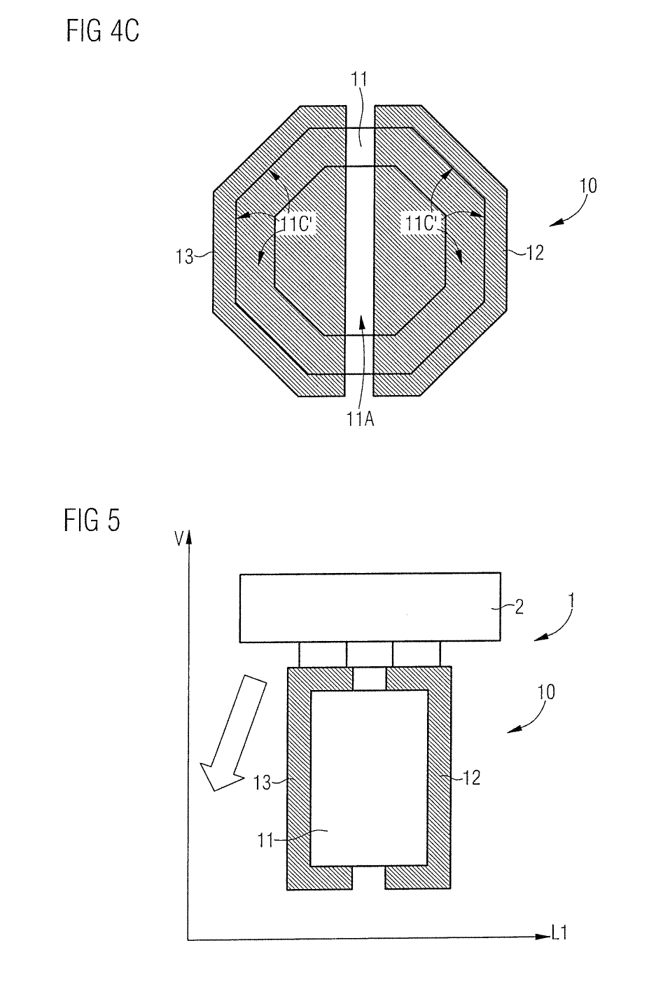

In the semiconductor components 1 illustrated in FIGS. 4A and 4B, the semiconductor chip 2 or the semiconductor body can have a cuboid shape in accordance with the first and second examples. In contrast thereto, the carrier 10 or base body 11 in cross section does not have a quadrangular, but a hexagonal (see FIG. 4A) or octagonal shape (see FIG. 4B). Both the base body 11 according to the fourth example (see FIG. 4A) and the base body 11 according to the fifth example (see FIG. 4B) can have an octagonal shape in plan view (see FIG. 4C). So, in the fourth and fifth examples, the base body 11 is delimited by eight side surfaces. Furthermore, the side surfaces are each composed of a plurality of partial surfaces 11C′. According to the fourth example, the side surfaces can each comprise two partial surfaces 11C′, wherein the two partial surfaces 11C′ are flat surfaces, the surface normals of which run transversely, that is to say not in parallel, to one another. According to the fifth example, the side surfaces can each comprise three partial surfaces 11C′, wherein the partial surfaces 11C′ are flat surfaces, the surface normals of which run transversely, that is to say not in parallel to one another. By the approximation to a hemispherical or spherical shape, as is the case in the fourth or fifth example, the decoupling of radiation from the base body can be improved.

In the example of a semiconductor component 1 illustrated in FIG. 5, the semiconductor chip 2 laterally projects beyond the carrier 10. In other words, the semiconductor chip 2 has a greater lateral extent than the carrier 10. As a result, the radiation can be emitted in the projecting region of the semiconductor chip 2 on the side facing the carrier 10 in a substantially unreduced way, that is to say without significant absorption losses at the carrier 10 (see arrow).

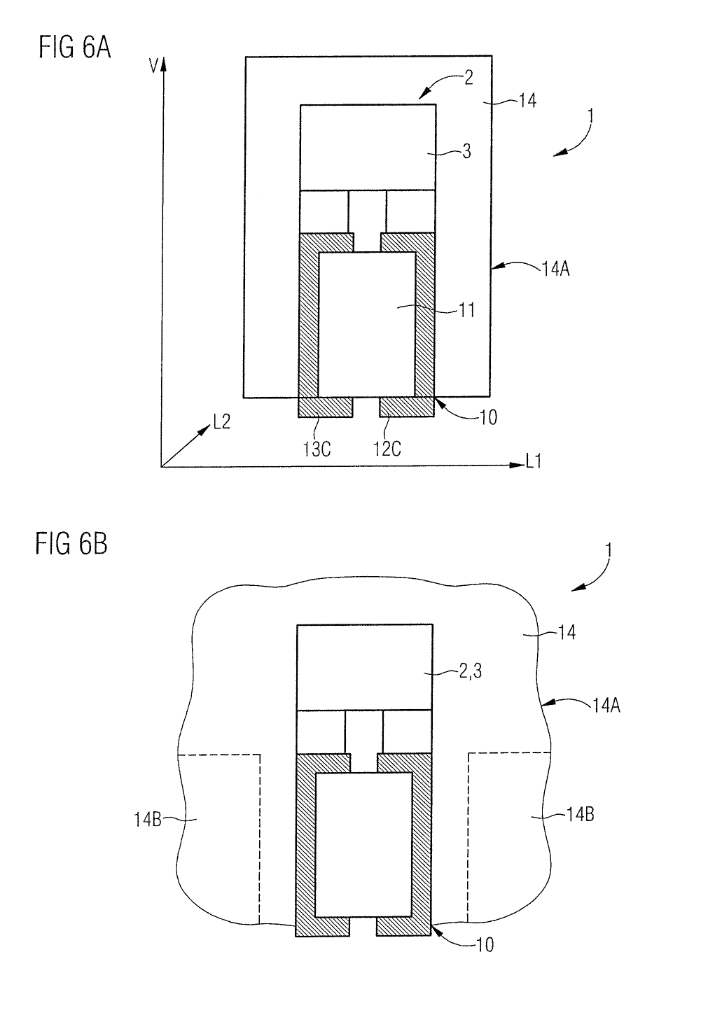

FIG. 6A shows a further example of a semiconductor component 1. With regard to the semiconductor chip 2 and the carrier 10, the semiconductor component 1 preferably does not differ from the preceding examples. However, the semiconductor component 1 comprises a cover element 14 which at least partially covers surfaces of the semiconductor chip 2 and of the carrier 10. The cover element 14 is arranged downstream of the carrier 10 and the semiconductor chip 2 in lateral directions L1, L2 and protrudes the semiconductor chip 2 in the vertical direction V. In particular, the third partial regions 12C, 13C of the first and second contact layer 12, 13 are uncovered by the cover element 14. This allows the semiconductor component 1 to be electrically conductively connected by the third partial regions 12C, 13C of the first and second contact layer 12, 13, that is to say, for example, to be electrically conductively connected to a connection carrier such as a printed circuit board. The semiconductor component 1 is thus surface-mountable.

The cover element 14 is preferably formed of plastic. Preferably, the cover element 14 is formed of the same material as the base body 11 of the carrier 10. In particular, the cover element 14 is a sealing, in which the unit comprising the semiconductor chip 2 and carrier 10 is embedded. The sealing can be formed mainly of a radiation-transmissive material. In this context, “radiation-transmissive” also means in particular that at most 50%, preferably at most 10%, of the radiation emitted by the semiconductor body 3, which impinges on the cover element 14, is absorbed by the material used for the cover element 14. In this case, the material of the cover element 14 can be transparent, that is to say allows for clear sight, or can be translucent, that is to say diffusely scattering. A comparatively high decoupling of radiation can be achieved by the radiation-transmissive material.

The cover element 14 has an outer surface 14A, that is to say a surface which delimits the semiconductor component 1 to the outside, which is similar to the surface of a geometric body, namely a cuboid.

In the semiconductor component 1 illustrated in FIG. 6B, however, the outer surface 14A is a free-form surface. This means that the outer surface 14A comprises regions which can be approximated by the surfaces of different geometric bodies. In particular, the outer surface 14A comprises regions which are curved differently. Optionally, the cover element 14 can comprise recesses 14B which bring about an enlargement of the outer surface 14A and thus of the luminous surface.

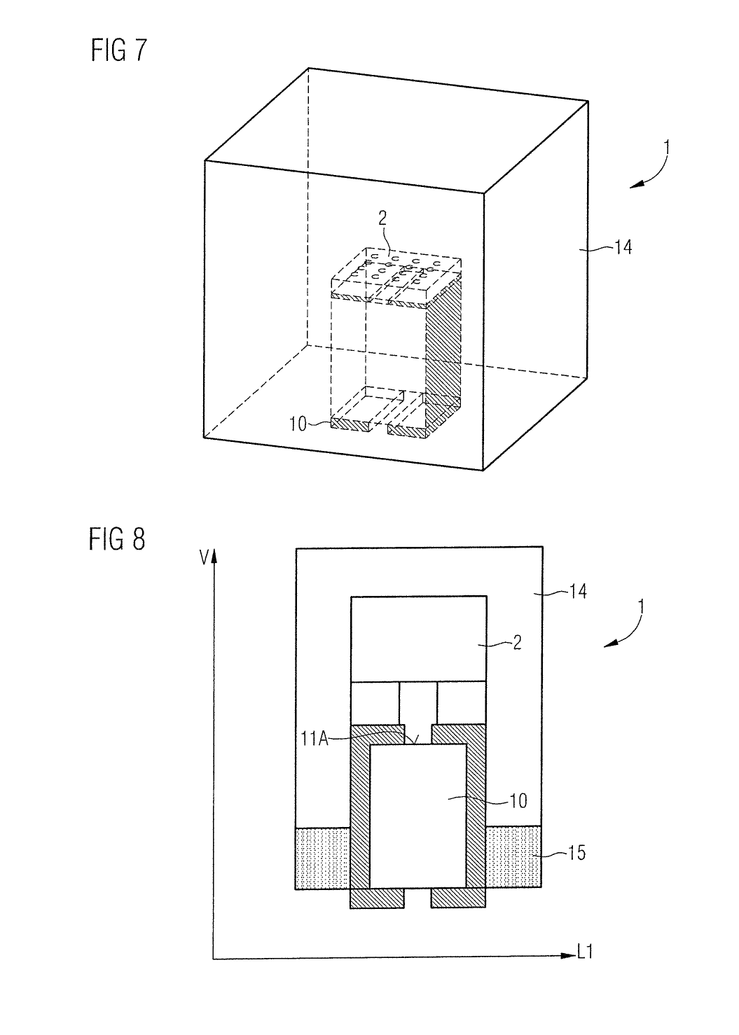

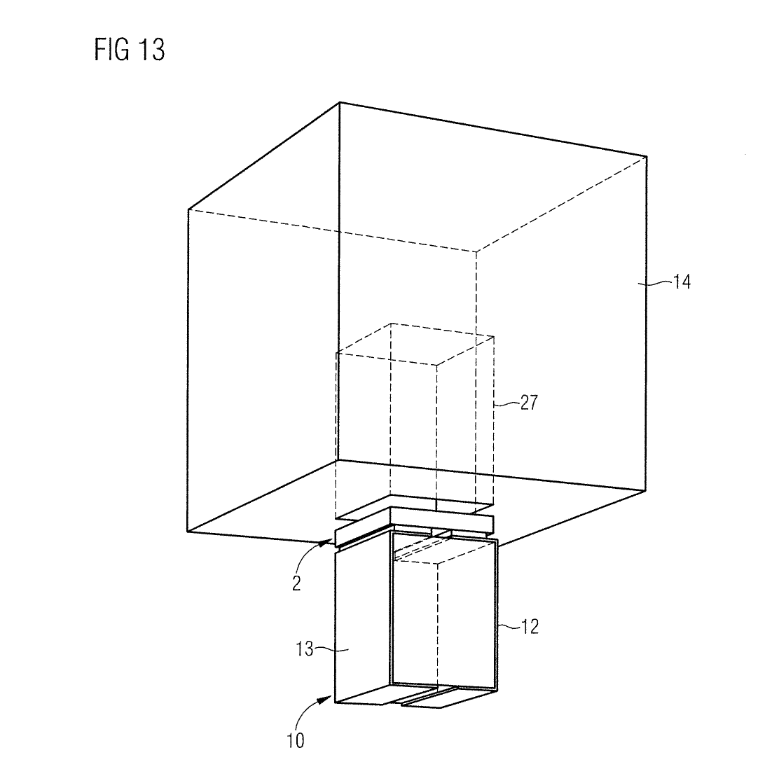

FIG. 7 shows a further example of a semiconductor component 1. With regard to the semiconductor chip 2 and the carrier 10, the semiconductor component 1 preferably does not differ from one of the first to sixth examples. The semiconductor component 1, however, comprises a cover element 14. The cover element 14 is a self-supporting three-dimensional element which is cuboid, for example, cubic. The cover element 14 comprises an opening 27 (see FIG. 13) into which the unit comprising the semiconductor chip 2 and carrier 10 is inserted. In particular, the opening 27 corresponds in shape and size to the unit comprising the semiconductor chip 2 and carrier 10. A mechanical connection between the cover element 14 and the component unit can be achieved, for example, by the cover element 14 being melted at its underside. After cooling, the cover element 14 is then fixed to the carrier 10. In particular, the cover element 14 is formed from glass, preferably borosilicate glass.

FIG. 8 shows a further example of a semiconductor component 1. With regard to the semiconductor chip 2, carrier 10 and the type of cover element 14, the semiconductor component 1 preferably does not differ from the seventh to ninth examples. However, the semiconductor component 1 comprises a reflector element 15, which encloses the carrier 10 in lateral directions L1, L2 and does not protrude the chip mounting surface 11A of the carrier 10 in the vertical direction V. The reflector element 15 is an integral part of the cover element 14. For example, the sealing can for this purpose contain reflecting particles such as particles made of TiO₂, for example. Alternatively, the reflector element 15 can be a reflective coating with which the cover element 14 is provided.

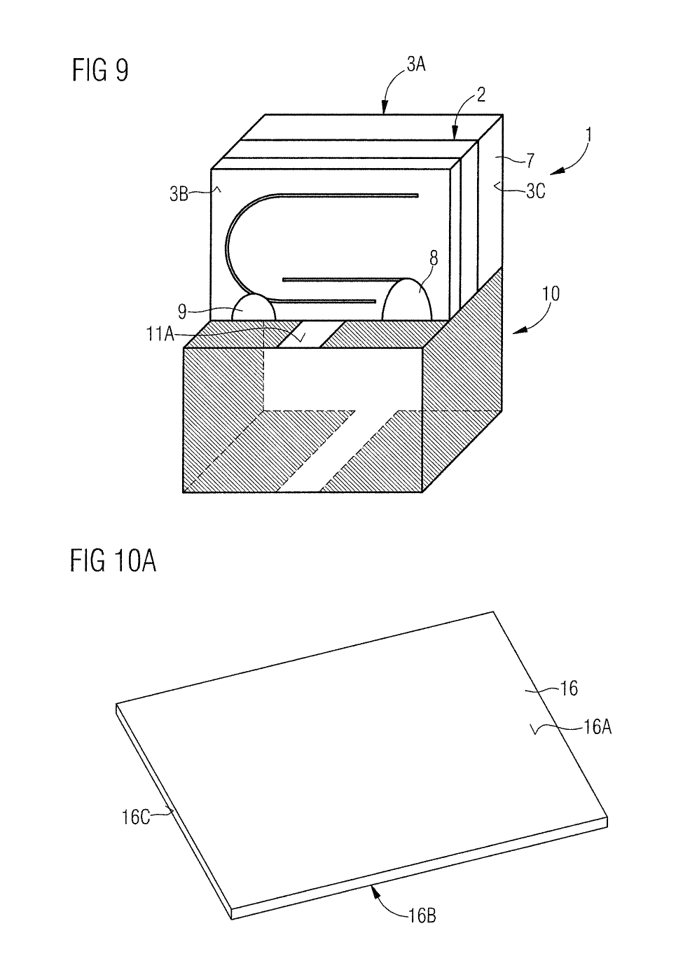

FIG. 9 shows a further example of a semiconductor component 1. With regard to the carrier 10, the semiconductor component 1 does not differ, for example, from the preceding examples. However, the semiconductor chip 2 differs with regard to its mounting on the carrier 10. While in the preceding examples the semiconductor chip 2 is mounted on the carrier 10 such that the first and second main surface 3A, 3B of the semiconductor body 3 run in parallel to the chip mounting surface 11A, in this example, the first and second main surface 3A, 3B are arranged transversely, in particular perpendicularly, to the chip mounting surface 11A. The semiconductor chip 2 is mounted on one of the side surfaces 3C of the semiconductor body 3. Both connection contacts 8, 9 are located on the second main surface 3B. As a result of mounting on the side surface 3C, both main surfaces 3A, 3B are uncovered by the carrier 10 so that the radiation decoupled at the main surfaces 3A, 3B can emerge essentially without disturbance from the semiconductor component 1 and in this way the radiation efficiency of the component 1 can be improved.

In conjunction with FIGS. 10A to 10G, a first variant of a method of producing at least one semiconductor component is described.

In a first step for producing at least one semiconductor component, a base body unit 16 is provided (see FIG. 10A). The base body unit 16 has a first surface 16A and a second surface 16B opposite the first surface 16A and at least one outer surface 16C, which connects the first surface 16A to the second surface 16B. The base body unit 16 is a cuboid unit, in particular a plate. The base body unit 16 can be formed of glass or plastic. A base body unit 16 formed of plastic can be produced, for example, by a molding method as described above.

In a next step (see FIG. 10B), the base body unit 16 is structured, that is to say base body elements 17 and recesses 18 are formed in the base body unit 16. For example, the recesses 18 in the base body unit 16 can be produced by hot stamping. The base body unit 16 is heated, and the recesses 18 are produced in the base body unit 16 by a stamping tool. Furthermore, the recesses 18 can be produced by mechanical and/or chemical processing such as, for example, lasering, sawing, etching.

The recesses 18 are delimited laterally, that is to say at least in the lateral direction L1, by the base body elements 17. In the illustrated example, the recesses 18 extend from the first surface 16A through the base body unit 16 to the second surface 16B. Furthermore, the recesses 18 extend in a main extension direction, which runs in parallel to the lateral direction L2, almost to the outer surfaces 16C. For example, the base body elements 17 can have a first lateral extent which is to be determined in the lateral direction L1 and is approximately 1 mm. Furthermore, the base body elements 17 can have a vertical extent which is to be determined in the vertical direction V and is also approximately 1 mm. Furthermore, the base body elements 17 can have a second lateral extent which is to be determined in the lateral direction L2 and is approximately 1 m. The recesses 17 can have identical dimensions.

In a further step (see FIG. 10C), the structured base body unit 16 is introduced with its second surface 16B into a mold 19, wherein the mold 19 comprises elevations, which engage in the recesses of the base body unit 16 and partially cover the side surfaces 17A of the base body elements 17. In FIGS. 10C to 10E, only a section of the base body unit 16 or of the mold 19 is illustrated. Preferably, the degree of coverage of the side surfaces 17A by the elevations of the mold 19 in the vertical direction is more than 50% and in the lateral direction, in particular, 100%.

A contact coating 20 is produced on uncovered regions of the base body unit 16, wherein the contact coating 20 is applied to the first surface 16A and to side surfaces 17A of the base body elements 17. Preferably, the first surface 16A of the base body unit 16 is completely covered by the contact coating 20. In particular, the contact coating 20 is a metallization. Suitable materials for the contact coating 20 are, for example, Cu, Ni, Au, AuSn. For example, a basic layer of the contact coating 20 can be sputtered on. The basic layer can be reinforced galvanically.

In a further step (see FIG. 10D), the structured base body unit 16 is introduced with its first surface 16A into the mold 19, wherein the elevations of the mold 19 engage in the recesses of the base body unit and partially cover the side surfaces 17A of the base body elements 17. Preferably, the degree of coverage of the side surfaces 17A by the elevations of the mold 19 in the vertical direction is preferably more than 50% and in the lateral direction, in particular, 100%.

The contact coating 20 is produced on uncovered regions of the base body unit 16, wherein the contact coating 20 is applied to the second surface 16B and to side surfaces 17A of the base body elements 17. Preferably, the second surface 16B of the base body unit 16 is completely covered by the contact coating 20.

In a further step (see FIG. 10E), the base body unit provided with the contact coating 20 is taken out of the mold. The contact coating 20 produced comprises at the side surfaces 17A in each case an interruption 21, which extends in the lateral direction L2 (see FIG. 10B).

In a further step (see FIG. 10F), the carrier unit formed of the base body unit and the contact coating is singulated into a plurality of carrier elements 22, which in each case comprise a base body element 17 and a first and second contact region 20A, 20B resulted from the contact coating 20, wherein the first and second contact region 20A, 20B are separated by interruptions 21 from one another. For example, the singulation of the carrier unit into a plurality of carrier elements 22 can be carried out by dividing by a water jet or sandjet if the base body unit is made of glass. Moreover, a singulation is possible by laser separation or sawing.

In a further step (see FIG. 10G), a component assembly 23 is formed, wherein a plurality of semiconductor chips 2 are applied to a carrier element 22 such that their first connection contacts 8 are electrically conductively connected to the first contact region 20A and their second connection contacts 9 are electrically conductively connected to the second contact region 20B.

In a further step (not shown), the component assembly 23 is singulated into a plurality of semiconductor components, wherein each semiconductor component comprises at least one semiconductor chip (see FIGS. 1A and 1B). The singulation of the component assembly 23 can be effected, for example, by laser separation or sawing.

Such a method, in which the production of holes in the carrier and the filling thereof is omitted, represents a cost-efficient method of producing semiconductor components.

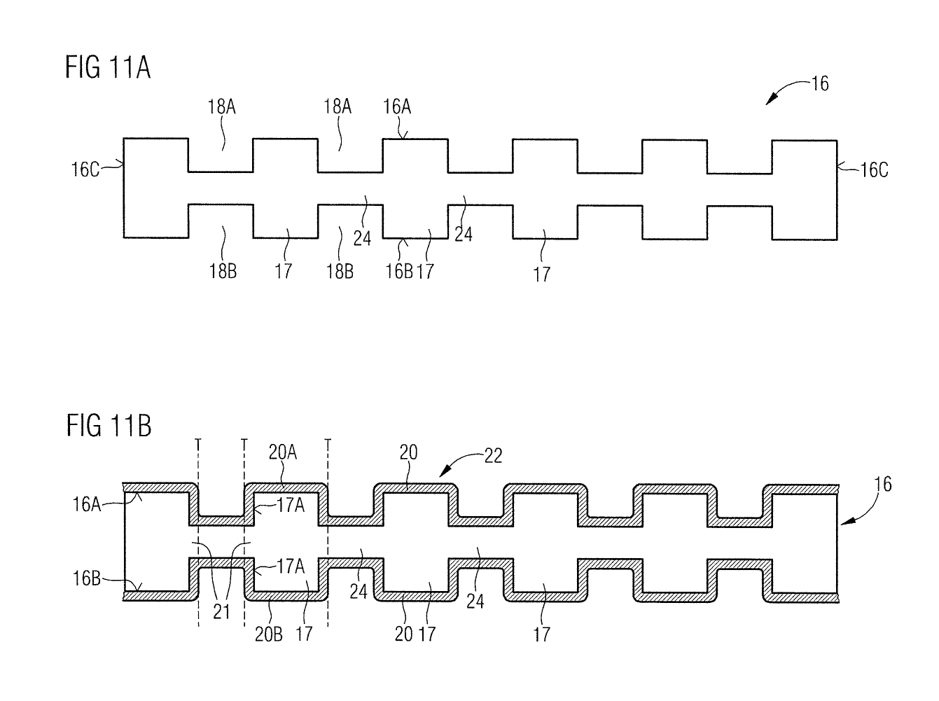

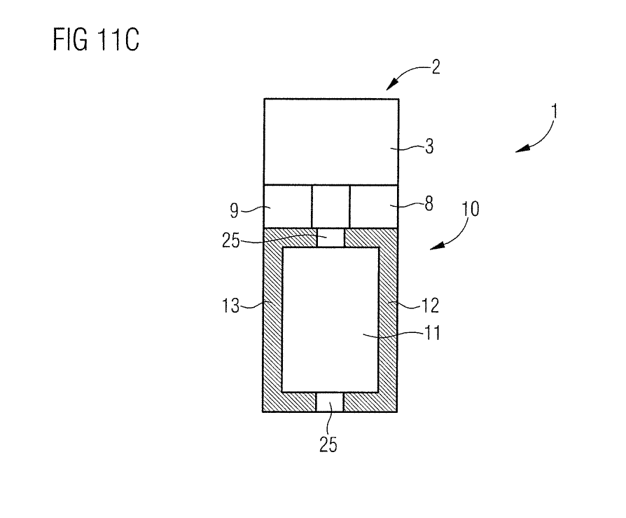

According to the second variant of a method illustrated in connection with FIGS. 11A to 11C, a base body unit 16 is first provided, which has a first surface 16A and a second surface 16B opposite the first surface 16A, and at least one outer surface 16C, which connects the first surface 16A to the second surface 16B. The base body unit 16 is provided with a structuring such that the base body unit 16 comprises base body elements 17 and recesses 18A, 18B. The recesses 18A, 18B are laterally delimited by the base body elements 17. Furthermore, the recesses 18A, 18B end in the base body unit 16, wherein a web 24 is arranged in each case between a recess 18A protruding from the first surface 16A into the base body unit 16 and a recess 18B protruding from the second surface 16B into the base body unit 16 (see FIG. 11A).

Subsequently (see FIG. 11B), a carrier unit is formed, wherein a contact coating 20 is applied to the first and the second surface 16A, 16B of the base body unit 16 and to side surfaces 17A of the base body elements 17. The webs 24 regionally prevent a deposition of the contact coating 20 on the side surfaces 17A of the adjacent base body elements 17. During the singulation of the carrier unit along the separating lines T, the webs 24 are removed. As a result, the contact coating 20 comprises interruptions 21 on the side surfaces 17A. The interruptions 21 contain the base material, from which the base body unit 16 is formed. The base material simultaneously forms an insulation between the first and second contact region 20A, 20B of the carrier elements 22.

Finally, a component assembly is produced by mounting a plurality of semiconductor chips on the individual carrier elements. The component assembly can then be singulated into a plurality of semiconductor components 1, each comprising at least one semiconductor chip 2 and a carrier 10, on which the semiconductor chip 2 is arranged (see FIG. 11C). The carrier 10 comprises between the first and second contact layer 12, 13 insulations 25 which are formed of the base material of the base body 11.

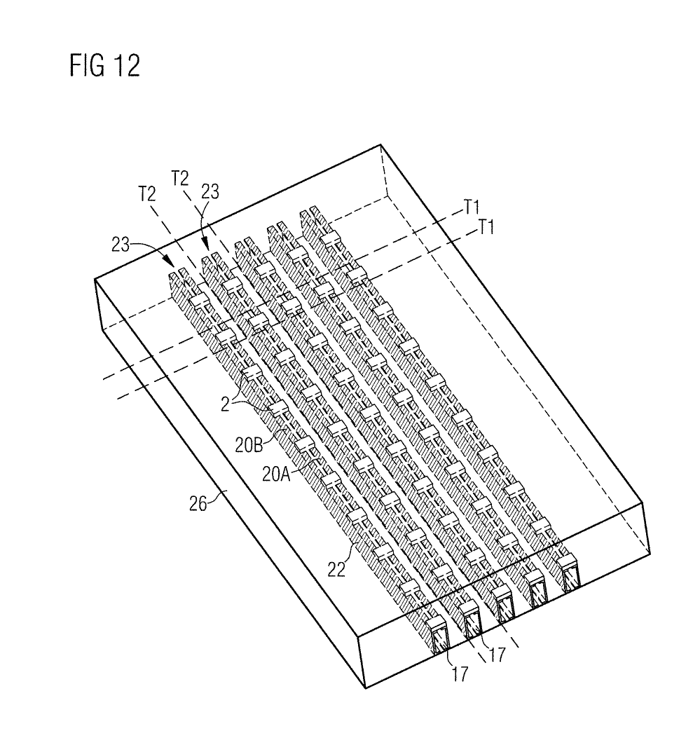

FIG. 12 shows a method step for producing semiconductor components which each comprise a cover element. A plurality of component assemblies 23 are provided, each of which comprise a carrier element 22 and a plurality of semiconductor chips 2 arranged thereon. The carrier elements 22 each comprise a first and second contact region 20A, 20B as well as a base body element 17 on which the contact regions 20A, 20B are arranged. The component assemblies 23 can be produced using one of the methods described above according to the first variant or according to the second variant.

The component assemblies 23 are embedded in an enclosure 26 so that their surfaces are for the most part covered by the enclosure 26. An exception are the contact regions 20A, 20B at the undersides of the component assemblies 23. These regions 20A, 20B remain uncovered by the enclosure 26. Preferably, the enclosure 26 is a sealing which contains a radiation-transmissive material. By singulation along the separating lines T1, T2 semiconductor components are produced which comprise a part of the enclosure 26 which forms a cover element 14 in the semiconductor components (see also FIGS. 6A and 6B).

FIG. 13 also shows a method step of producing a semiconductor component comprising a cover element 14 (see FIGS. 7 and 8). The unit comprising the semiconductor chip 2 and carrier 10 can be produced using one of the methods described above according to the first variant or according to the second variant. The cover element 14 is a self-supporting three-dimensional element. In particular, the cover element 14 is formed of glass. The cover element 14 comprises an opening 27 into which the unit comprising the semiconductor chip 2 and carrier 10 is inserted. The opening 27 corresponds in shape and size to the unit comprising the semiconductor chip 2 and carrier 10. A mechanical connection between the cover element 14 and the component unit can be achieved by the cover element 14 being melted at its underside. After cooling, the cover element 14 is then fixed to the carrier 10. Temperatures around 600° C. are typically required for melting. If these occur in the region of the semiconductor chip 2, the latter can be destroyed. Advantageously, due to the distance to the semiconductor chip 2 in its immediate vicinity maximum temperatures of 300° C., which are not critical for the semiconductor chip 2, occur during melting at the underside of the cover element 14.

Our components and methods are not restricted by the description on the basis of the examples. Rather, this disclosure encompasses any novel feature and also any combination of features, which in particular includes any combination of features in the appended claims, even if the feature or combination itself is not explicitly specified in the claims or examples.

This application claims priority of DE 102017103828.0, the subject matter of which is incorporated herein by reference.

1-17. (canceled)

18. A semiconductor component comprising:
a semiconductor chip comprising a semiconductor body and a first and second connection contact, wherein the first and second connection contact are provided to electrically contact the semiconductor body,
a carrier on which the semiconductor chip is arranged, the carrier comprising:
a base body comprising a chip mounting surface and a connection surface opposite the chip mounting surface and at least one side surface, that connects the chip mounting surface to the connection surface,
a first electrically conductive contact layer electrically conductively connected to the first connection contact, and a second electrically conductive contact layer electrically conductively connected to the second connection contact, wherein the first and the second contact layer are applied to the base body and each comprise a first partial region arranged on the chip mounting surface, a second partial region arranged on a side surface and a third partial region arranged on the connection surface, and wherein
the base body contains a radiation-transmissive base material.

19. The semiconductor component according to claim 18, wherein the second partial regions of the first and second contact layer are arranged on different side surfaces and cover between 50% and 100% of the respective side surface.

20. The semiconductor component according to claim 18, wherein the first partial regions of the first and second contact layer together cover at least 50% and less than 100% of the chip mounting surface.

21. The semiconductor component according to claim 18, wherein the third partial regions of the first and second contact layer together cover at least 50% and less than 100% of the connection surface.

22. The semiconductor component according to claim 18, wherein the second partial regions of the first and second contact layer are arranged on different side surfaces and cover more than 0% and less than 50% of the respective side surface.

23. The semiconductor component according to claim 22, wherein the first partial regions of the first and second contact layer cover more than 0% and less than 50% of the chip mounting surface.

24. The semiconductor component according to claim 22, wherein the third partial regions of the first and second contact layer cover more than 0% and less than 50% of the connection surface.

25. The semiconductor component according to claim 18, wherein the base body is free of contact elements in its interior.

26. The semiconductor component according to claim 18, further comprising a cover element at least partially covering surfaces of the semiconductor chip and the carrier.

27. The semiconductor component according to claim 26, wherein the base body and the cover element each contain or consist of at least one of glass and plastic.

28. The semiconductor component according to claim 26, wherein the semiconductor chip and the carrier are arranged within the cover element.

29. A method of producing at least one semiconductor component comprising:
providing a base body unit comprising a first surface and a second surface opposite the first surface and at least one outer surface, which connects the first surface to the second surface,
structuring of the base body unit in base body elements and recesses, wherein the recesses are laterally delimited by the base body elements, and the recesses extend from the first surface through the base body unit to the second surface or end in the base body unit such that a web is arranged in each case between a recess protruding from the first surface into the base body unit and a recess protruding from the second surface into the base body unit,
forming a carrier unit by applying a contact coating to the first and second surface and to side surfaces of the base body elements, wherein the contact coating at the side surfaces comprises in each case an interruption which extends in a lateral direction,
singulating the carrier unit into a plurality of carrier elements, each comprising a base body element and a first and second contact region, wherein the first and second contact region are separated from one another by interruptions,
forming a component assembly by applying semiconductor chips to a carrier element such that their first connection contacts electrically conductively connect to the first contact region and their second connection contacts electrically conductively connect to the second contact region, and
singulating the component assembly into a plurality of semiconductor components.

30. The method according to claim 29, wherein, to produce the interruptions in the contact coating, the following steps are carried out:
introducing the structured base body unit with its second surface into a mold, wherein the mold comprises elevations that engage in the recesses of the base body unit and partially cover the side surfaces of the base body elements,
producing the contact coating on uncovered regions of the base body unit,
introducing the structured base body unit with its first surface into the mold, wherein the elevations engage in the recesses of the base body unit and partially cover the side surfaces of the base body elements, and
producing the contact coating on uncovered regions of the base body unit.

31. The method according to claim 29, wherein a shadow mask produces the interruptions, the shadow mask during the coating process covering the positions at which deposition of the contact coating is to be prevented.

32. The method according to claim 29, wherein the interruptions in the contact coating are produced by removing the webs.

33. The method according to claim 29, wherein the semiconductor component comprises a cover element and the latter is melted at its underside, wherein the cover element is fixed to the carrier after cooling.
